(19) United States
(12) Patent Application Publication
(10) Pub. No.: US 2022/0278210 A1
(43) Pub. Date: Sep. 1, 2022

(54) SEMICONDUCTOR DEVICE, SEMICONDUCTOR MODULE, AND ELECTRONIC APPARATUS

(71) Applicant: Sony Semiconductor Solutions Corporation, Kanagawa (JP)

(72) Inventors: Katsuhiko Takeuchi, Kanagawa (JP); Masashi Yanagita, Kanagawa (JP)

(21) Appl. No.: 17/628,376

(22) PCT Filed: Jul. 17, 2020
(86) PCT No.: PCT/JP2020/027822

§ 371 Date: Jan. 19, 2022

(30) Foreign Application Priority Data
Aug. 9, 2019 (JP) 2019-147801

(51) Int. Cl. H01L 29/417; H01L 29/778; H01L 29/66

(52) U.S. Cl. CPC H01L 29/41758; H01L 29/7786; H01L 29/66462; H01L 29/2003

(57) ABSTRACT

A semiconductor device includes: a semiconductor layer including a channel layer; a contact region provided at a predetermined size in a thickness direction of the semiconductor layer, and having an impurity concentration that is higher than an impurity concentration of the surrounding semiconductor layer; a gate electrode facing the channel layer, and provided on the semiconductor layer and spaced from the contact region; and an electrode that is in contact with the semiconductor layer and electrically coupled to the channel layer via the contact region, and extending more on at least the gate electrode side than the contact region.

### TECHNICAL FIELD

The present technology relates to a semiconductor device having a semiconductor layer and a gate electrode, and to a semiconductor module and an electronic apparatus provided with the semiconductor device.

### BACKGROUND ART

A semiconductor device such as a field-effect transistor (FET: Field Effect Transistor) has, for example: a semiconductor layer including a channel layer; and a pair of electrodes (a source electrode and a drain electrode) electrically coupled to the channel layer (see, for example, Patent Literature 1). For example, the semiconductor layer includes a region in which N-type impurities are diffused at a high concentration, and the source electrode and the drain electrode are each electrically coupled to the channel layer via the high-concentration impurity diffusion region.

### CITATION LIST

### Patent Literature

Patent Literature 1: Japanese Unexamined Patent Application Publication No. 2017-163082

### SUMMARY OF THE INVENTION

In such a semiconductor device, it is desired to improve a transistor characteristic.

It is desirable to provide a semiconductor device that makes it possible to improve a transistor characteristic, and a semiconductor module and an electronic apparatus provided with the semiconductor device.

A semiconductor device according to one embodiment of the present technology includes: a semiconductor layer including a channel layer; a contact region provided at a predetermined size in a thickness direction of the semiconductor layer, and having an impurity concentration that is higher than an impurity concentration of the surrounding semiconductor layer; a gate electrode facing the channel layer, and provided on the semiconductor layer and spaced from the contact region; and an electrode that is in contact with the semiconductor layer and electrically coupled to the channel layer via the contact region, and extending more on at least the gate electrode side than the contact region.

A semiconductor module according to one embodiment of the present technology includes the semiconductor device according to one embodiment of the present technology described above.

An electronic apparatus according to one embodiment of the present technology includes the semiconductor device according to one embodiment of the present technology described above.

In the semiconductor device, the semiconductor module, and the electronic apparatus according to one embodiment of the present technology, the electrode extends more on at least the gate electrode side than the contact region. Thus, an influence of a sheet resistance of the contact region is suppressed as compared with a case where the contact region is exposed from the electrode.

### BRIEF DESCRIPTION OF THE DRAWINGS

FIG. 1 is a schematic a cross-sectional diagram illustrating a configuration of a main part of a semiconductor device according to an embodiment of the present technology.

FIG. 2 is a schematic diagram illustrating an upper surface configuration of the semiconductor device illustrated in FIG. 1.

FIG. 3 is an energy band configuration diagram of the semiconductor device (Vg=0V) illustrated in FIG. 1.

FIG. 4A is a schematic cross-sectional diagram illustrating a manufacturing process of the semiconductor device illustrated in FIG. 1.

FIG. 4B is a schematic cross-sectional diagram illustrating a process following FIG. 4A.

FIG. 4C is a schematic cross-sectional diagram illustrating a process following FIG. 4B.

FIG. 4D is a schematic cross-sectional diagram illustrating a process following FIG. 4C.

FIG. 4E is a schematic cross-sectional diagram illustrating a process following FIG. 4D.

FIG. 4F is a schematic cross-sectional diagram illustrating a process following FIG. 4E.

FIG. 5 is an energy band configuration diagram of the semiconductor device (upon an off operation) illustrated in FIG. 1.

FIG. 6 is a cross-sectional diagram schematically illustrating a carrier deficiency region formed upon the off operation of the semiconductor device illustrated in FIG. 1.

FIG. 7 is a schematic cross-sectional diagram illustrating a configuration of a main part of a semiconductor device according to a comparative example.

FIG. 8 is a diagram illustrating a relationship between distances illustrated in FIG. 1 and an on resistance.

FIG. 9 is a schematic cross-sectional diagram illustrating a configuration of a main part of a semiconductor device according to modification example 1.

FIG. 10A is a schematic cross-sectional diagram illustrating a manufacturing process of the semiconductor device illustrated in FIG. 9.

FIG. 10B is a schematic cross-sectional diagram illustrating a process following FIG. 10A.

FIG. 10C is a schematic cross-sectional diagram illustrating a process following FIG. 10B.

FIG. 10D is a schematic cross-sectional diagram illustrating a process following FIG. 10C.

FIG. 11 is a schematic cross-sectional diagram illustrating a configuration of a main part of a semiconductor device according to modification example 2.

FIG. 12 is a schematic cross-sectional diagram illustrating a manufacturing process of the semiconductor device illustrated in FIG. 11.

FIG. 13 is a block diagram illustrating an example of a configuration of a wireless communicator to which the semiconductor device illustrated in FIG. 1 or the like is applied.

FIG. 14 is a schematic cross-sectional diagram illustrating another example of the semiconductor device illustrated in FIG. 1 or the like.

FIG. 15 is a schematic plan diagram illustrating another example of the semiconductor device illustrated in FIG. 2 or the like.

### MODES FOR CARRYING OUT THE INVENTION

The following describes an embodiment of the present technology in detail with reference to the drawings. Note that the description will be made in the following order.

1. Embodiment

A semiconductor device having a source electrode and a drain electrode that extend more on the gate electrode side than a contact region.

2. Modification Example 1

An example in which an interlayer insulation film has a stacked structure.

3. Modification Example 2

An example in which a gate insulation film is provided between a gate electrode and a semiconductor layer.

### Embodiment

(Configuration of Semiconductor Device 1)

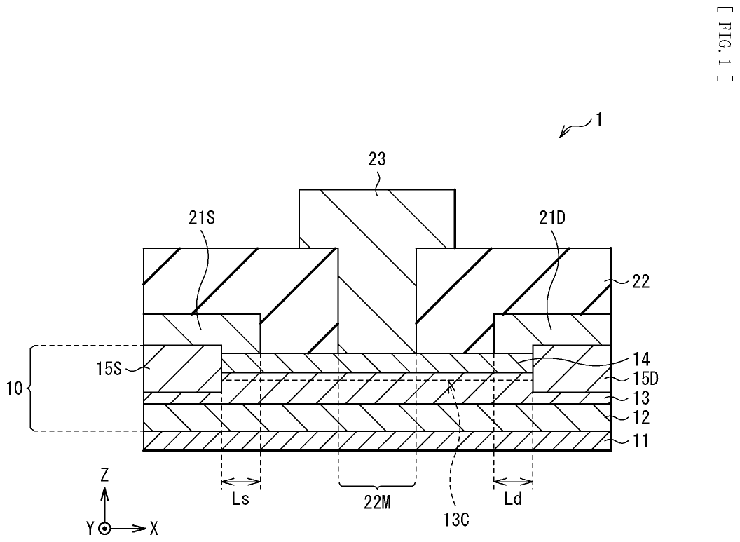

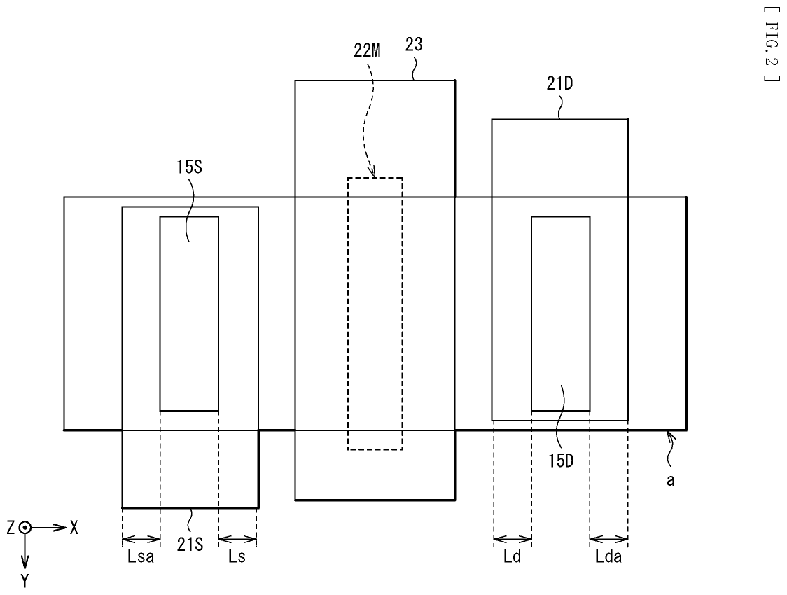

FIG. 1 is a cross-sectional diagram illustrating a main part configuration of a semiconductor device (a semiconductor device 1) according to an embodiment of the present technology. FIG. 2 is an upper diagram of the semiconductor device 1. A detailed configuration of the semiconductor device 1 will be described below on the basis of these drawings.

The semiconductor device 1 has: a semiconductor layer 10 including a channel layer 13; a source electrode 21S and a drain electrode 21D; an interlayer insulation film 22; and a gate electrode 23 in this order on a substrate 11. The interlayer insulation film 22 has an opening 22M in a selective region, and a portion of the gate electrode 23 is embedded in the opening 22M. The gate electrode 23 has a so-called T-shaped cross-sectional structure. The gate electrode 23, the source electrode 21S, and the drain electrode 21D that are provided on the semiconductor layer 10 are spaced apart from each other, and the source electrode 21S, the gate electrode 23, and the drain electrode 21D are disposed in this order in a channel length direction (in an X-direction in FIG. 2).

The substrate 11 includes a semiconductor material. Such a substrate 11 includes, for example, a group III-V compound semiconductor material. For example, a semi-insulating single-crystal GaN (gallium nitride) substrate is used for the substrate 11. It is also possible to use a substrate material having a lattice constant different from a lattice constant of the channel layer 13 for the substrate 11. Examples of a constituent material of such a substrate 11 include SiC (silicon carbide), sapphire, and Si (silicon). At this time, the lattice constant is adjusted by a buffer layer (a buffer layer 12 described later) provided between the substrate 11 and the channel layer 13. An island-shaped active region a is provided on an upper part of the substrate 11 (FIG. 2). A location between the adjacent active regions a is isolated by ion implantation or the like of B (boron), for example. Thus, the multiple active regions a are treated with an element isolation. Each active region a is provided with the gate electrode 23, the source electrode 21S, the drain electrode 21D, and the like. The element isolation may be performed by a method other than the ion implantation. For example, the channel layer 13 may be divided by dry-etching to perform the element isolation.

The semiconductor layer 10 has a structure in which, for example, the buffer layer 12, the channel layer 13, and a barrier layer 14 are stacked in order from the substrate 11 side.

The buffer layer 12 is configured by, for example, a compound semiconductor layer epitaxially grown on the substrate 11, and is configured by using a compound semiconductor that is lattice-matched in a favorable fashion to the substrate 11. For example, an epitaxial growth layer having u-GaN in which no impurities are added (u-represents that no impurities are added; the same applies hereinafter) is provided on the substrate 11 configured by a single-crystal GaN substrate. It is possible to improve a crystalline state of the channel layer 13 and to suppress a warpage of a wafer by providing the buffer layer 12 between the substrate 11 and the channel layer 13, when the lattice constant of the substrate 11 and the lattice constant of the channel layer 13 are different from each other. For example, in a case where the substrate 11 is configured by Si and the channel layer 13 is configured by GaN, it is possible to use, for example, AlN (aluminum nitride), AlGaN (aluminum nitride gallium), GaN or the like for the buffer layer 12. The buffer layer 12 may be configured by a single layer or may have a stacked structure. When the buffer layer 12 includes ternary materials, respective compositions thereof may be varied gradually in the buffer layer 12.

The channel layer 13 provided between the buffer layer 12 and the barrier layer 14 is a current path between the source electrode 21S and the drain electrode 21D. In the channel layer 13, carriers are accumulated by polarization with the barrier layer 14, and a two-dimensional electron-gas (2DEG: Two Dimensional Electron gas) layer 13c is provided in the vicinity of a junction surface (a heterojunction interface) with the barrier layer 14. That is, the semiconductor device 1 is a GaN-based hetero-field-effect transistor (HFET). It is preferable that such a channel layer 13 include a compound semiconductor material in which carriers are easily accumulated by the polarization with the barrier layer 14. For example, the channel layer 13 is configured by GaN epitaxially grown on the buffer layer 12. The channel layer 13 may be configured by the u-GaN in which no impurities are added. The channel layer 13 configured by the u-GaN suppresses the impurity scattering of the carriers in the channel layer 13 and thus makes it possible to increase mobility of the carriers.

GaN is a wide-gap semiconductor material and is high in breakdown voltage. Further, the semiconductor layer 10 containing GaN allows for a high temperature operation and is also high in saturated drifting velocity. The two dimensional electron gas layer 13c formed at the channel layer 13 containing GaN is high in mobility and high in sheet-electron density. The semiconductor device 1 which is the GaN-based hetero-field-effect transistor allows for low-resistance, high-speed, and high withstand voltage operation, and is suitably used in a power device, an RF (Radio Frequency) device, and the like.

A lower barrier layer (not illustrated) may be provided between the channel layer 13 and the buffer layer 12. Providing the lower barrier layer makes it possible to suppress the spread of electron distribution on the buffer layer 12 side in the channel layer 13. This makes it possible to suppress a short-channel effect and the like and to improve a transistor characteristic.

The barrier layer 14 provided between the channel layer 13 and the interlayer insulation film 22 forms a heterojunction interface with the channel layer 13. The barrier layer 14 includes, for example, a compound semiconductor material having a band gap wider than a band gap of the channel layer 13. For example, Al_{(1-x-y)}GaₓIn_{y}N (0≤x<1, 0≤y<1) epitaxially grown on the channel layer 13 is used for the barrier layer 14. The barrier layer 14 may be configured by u-Al_{(1-x-y)}GaₓIn_{y}N in which no impurities are added. Using the barrier layer 14 configured by u-Al_{(1-x-y)}GaₓIn_{y}N suppresses impurity scattering of the carriers in the channel layer 13, thereby making it possible to increase the mobility of carriers. The barrier layer 14 may be configured by a single layer or may have a stacked structure. For example, the barrier layer 14 may be configured by a stacked structure of Al_{(1-x-y)}GaₓIn_{y}N having compositions different from each other. Alternatively, a composition of each Al_{(1-x-y)}GaₓIn_{y}N may be made gradually different in the barrier layer 14.

The semiconductor layer 10 is provided with a source-side contact region 15S and a drain-side contact region 15D that are disposed in such a manner as to be separated from each other. The source-side contact region 15S and the drain-side contact region 15D are regions having an impurity concentration higher than an impurity concentration of any other part of the semiconductor layer 10, and are provided at a predetermined size in a thickness direction (in a Z-direction in FIG. 1) of the semiconductor layer 10. For example, the source-side contact region 15S and the drain-side contact region 15D are provided from a surface of the semiconductor layer 10 (a surface on the opposite side of the substrate 11) to a portion in a thickness direction of the channel layer 13. The source-side contact region 15S is a region for electrically coupling the source electrode 21S and the two dimensional electron gas layer 13c at a low resistance, and the drain-side contact region 15D is a region for electrically coupling the drain electrode 21D and the two dimensional electron gas layer 13c at a low resistance. The source-side contact region 15S is disposed at a position overlapped with the source electrode 21S in a plan view (X-Y plane in FIG. 2), and the drain-side contact region 15D is disposed at a position overlapped with the drain electrode 21D in the plan view (X-Y plane in FIG. 2). Of the channel layer 13, the source-side contact region 15S and the drain-side contact region 15D are preferably formed up to a deeper position (a position distant from the surface) of the semiconductor layer 10 than a position near the barrier layer 14; however, the source-side contact region 15S and the drain-side contact region 15D may not be in contact with the two dimensional electron gas layer 13c.

The source-side contact region 15S and the drain-side contact region 15D include, for example, highly concentrated N-type impurities. The N-type impurity is, for example, Si (silicon), Ge (germanium), or the like. The concentration of the N-type impurities of the source-side contact region 15S and the drain-side contact region 15D is, for example, 1×10¹⁸ cm⁻³ or more.

The source-side contact region 15S and the drain-side contact region 15D may be formed by diffusing impurities from a surface of the semiconductor layer 10 into the barrier layer 14 and the channel layer 13, for example, using ion implantation. That is, the source-side contact region 15S and the drain-side contact region 15D may be provided in regions of portions of the barrier layer 14 and the channel layer 13.

The source-side contact region 15S and the drain-side contact region 15D may be configured by layers different from, for example, the barrier layer 14 and the channel layer 13. Such a source-side contact region 15S and drain-side contact region 15D are formed, for example, by removing portions of the barrier layer 14 and the channel layer 13 and thereafter filling a region from which the barrier layer 14 and the channel layer 13 are removed with a semiconductor material, as will be described later. At this time, the source-side contact region 15S and the drain-side contact region 15D are configured by, for example, In_{(1-z)}Ga_{z}N (0≤z<1) containing an N-type impurity. The source-side contact region 15S and the drain-side contact region 15D may be configured by a single layer or may have a stacked structure. For example, the source-side contact region 15S and the drain-side contact region 15D may be configured by a stacked structure of In_{(1-z)}Ga_{z}N having different compositions. Alternatively, respective compositions of In_{(1-z)}Ga_{z}N may be gradually varied in the source-side contact region 15S and in the drain-side contact region 15D.

The source electrode 21S and the drain electrode 21D are respectively disposed separately from each other in selective regions of a surface of the semiconductor layer 10. The source electrode 21S and the drain electrode 21D are both in contact with the surface of the semiconductor layer 10. That is, the source electrode 21S and the drain electrode 21D are each ohmically bonded to the semiconductor layer 10. In the present embodiment, the source electrode 21S covers the source-side contact region 15S and extends more on the gate electrode 23 side than the source-side contact region 15S at a predetermined distance (a distance Ls), and the drain electrode 21D covers the drain-side contact region 15D and extends more on the gate electrode 23 side than the drain-side contact region 15D at a predetermined distance (a distance Ld). As will be described later in detail, this suppresses an influence of a sheet resistance of the source-side contact region 15S and the drain-side contact region 15D as compared with a case where the source-side contact region 15S and the drain-side contact region 15D are exposed from the source electrode 21S and the drain electrode 21D.

The source electrode 21S is provided in a region wider than the source-side contact region 15S, for example, over the entire circumference of the source-side contact region 15S (FIG. 2). The source electrode 21S also extends at a distance Lsa on the opposite side of the gate electrode 23 in the channel length direction, for example. The source electrode 21S preferably extends on both sides of the source-side contact region 15S (on the gate electrode 23 side and on the opposite side of the gate electrode 23) in the channel length direction, but may extend more on at least the gate electrode 23 side than the source-side contact region 15S. The source electrode 21S is in contact with, for example, the source-side contact region 15S and the barrier layer 14 (FIG. 1).

The drain electrode 21D is provided in a region wider than the drain-side contact region 15D, for example, over the entire circumference of the drain-side contact region 15D (FIG. 2). The drain electrode 21D also extends at a distance Lda on the opposite side of the gate electrode 23 in the channel length direction, for example. The drain electrode 21D preferably extends on both sides of the drain-side contact region 15D in the channel length direction, but may extend more on at least the gate electrode 23 side than the drain-side contact region 15D. The drain electrode 21D is in contact with, for example, the drain-side contact region 15D and the barrier layer 14 (FIG. 1).

The source electrode 21S and the drain electrode 21D is configured by a laminated film in which, for example, titanium (Ti), aluminum (Al), nickel (Ni), and gold (Au) are stacked in this order from the semiconductor layer 10 side. A portion of each of the source electrode 21S and the drain electrode 21D may be provided so as to protrude from the active region a in a plan view (FIG. 2). The source electrode 21S and the drain electrode 21D may be coupled to a wiring line layer via contacts provided on upper parts thereof. This makes it possible to suppress a resistance component of a metal lead-out portion.

The interlayer insulation film 22 is so provided on the semiconductor layer 10 as to cover the source electrode 21S and the drain electrode 21D. The opening 22M of the interlayer insulation film 22 is so provided as to penetrate the interlayer insulation film 22. The opening 22M is disposed in the channel length direction between the source-side contact region 15S and the drain-side contact region 15D. For example, the opening 22M has a rectangular planar shape (FIG. 2). The interlayer insulation film 22 functions as an insulation film for the barrier layer 14 and has a function of protecting a surface of the barrier layer 14 from contamination caused by impurities. Examples of the impurity include ions. In addition, a good interface is formed between the interlayer insulation film 22 and the barrier layer 14, thereby suppressing a deterioration of a device characteristic. For example, the interlayer insulation film 22 is configured by SiO₂ (silicon oxide) or the like. The interlayer insulation film 22 may be configured by, for example, Al₂O₃ (aluminum oxide), silicon nitride (SiN), or the like.

The gate electrode 23 is provided on the interlayer insulation film 22 and is embedded in the opening 22M of the interlayer insulation film 22. A gate length (Lg) of the gate electrode 23 is defined by a size of the gate electrode 23 (a size in the X-direction in FIG. 1) of a portion embedded in the opening 22M. The gate electrode 23 is so disposed as to be spaced apart from the source-side contact region 15S and the drain-side contact region 15D. The gate electrode 23 is configured by a laminated film in which, for example, nickel (Ni) and gold (Au) are sequentially stacked from the substrate 11 side.

The gate electrode 23 of a portion facing the semiconductor layer 10 with the interlayer insulation film 22 in between, i.e., the gate electrode 23 on the interlayer insulation film 22, covers the opening 22M and widens around the opening 22M. The gate electrode 23 on the interlayer insulation film 22 is, for example, widened over the entire circumference of the opening 22M. The gate electrode 23 on the interlayer insulation film 22 may be widened over a portion of the circumference of the opening 22M. Providing the gate electrode 23 around the opening 22M increases the area (the cross-sectional area) of the gate electrode 23, thereby making it possible to decrease a gate resistance (Rg). The gate electrode 23 having such a T-shaped structure makes it possible to decrease the gate resistance while reducing a gate length, thereby making it possible to increase a cutoff frequency (fmax). Accordingly, the semiconductor device 1 having the gate electrode 23 is suitably used as a high-frequency device.

(Band-Structure of Semiconductor Device 1)

FIG. 3 is an energy band configuration diagram at a lower part of the gate electrode 23 of the semiconductor device 1 having the above-described configuration, and illustrates a bonding state in which no gate voltage Vg is applied. It should be noted that the energy band configuration diagram illustrates a case in which the channel layer 13 is configured by GaN and the barrier layer 14 is configured by an Al_{0.3}GA_{0.7}N mixed crystal, and in which a gate insulation film (a gate insulation film 24 illustrated in FIG. 11 to be described later) is provided between the gate electrode 23 and the barrier layer 14.

In the semiconductor device 1, the barrier layer 14 having a band gap wider than that of the channel layer 13 is bonded to the channel layer 13 having a narrower band gap. Thus, in the channel layer 13, the carriers are accumulated in the vicinity of the junction surface with the barrier layer 14 in the channel layer 13 by spontaneous polarization, piezoelectric polarization, or both. Thus, the two dimensional electron gas layer 13c is formed at the channel layer 13.

Further, a discontinuous amount ΔEc between a conduction band end of the channel layer 13 and a conductor end of the barrier layer 14 is sufficiently large (here, 0.3 eV). Thus, the number of carriers (electrons) distributed in the barrier layer 14 is negligibly small as compared with the number of carriers (electrons) distributed in the channel layer 13.

(Method of Manufacturing Semiconductor Device 1)

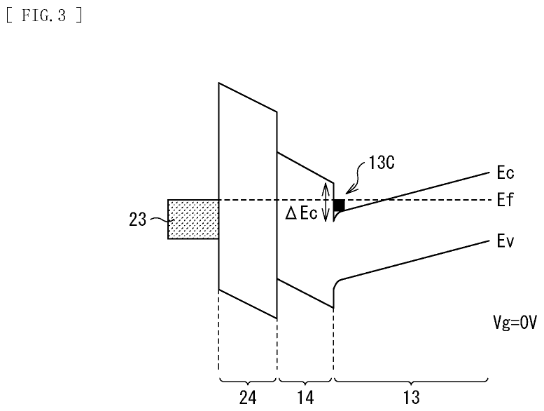

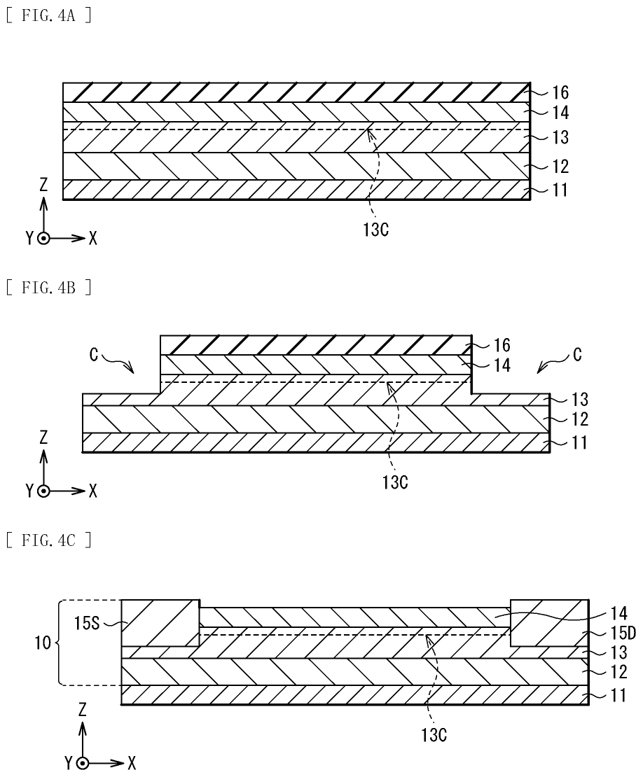

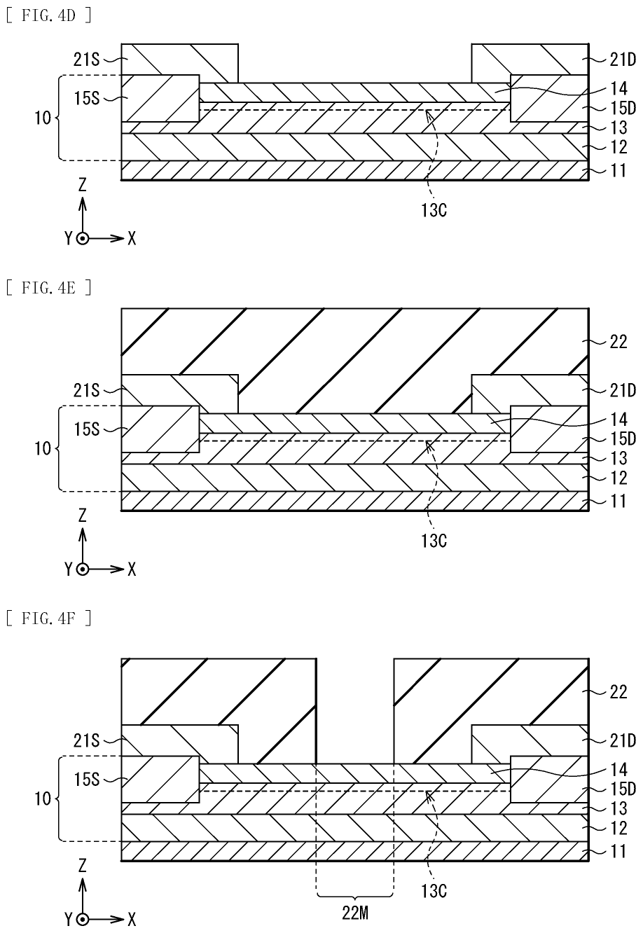

For example, it is possible to manufacture the semiconductor device 1 having a configuration described above as follows. FIGS. 4A to 4F are schematic cross-sectional diagrams illustrating a method of manufacturing the semiconductor device 1 in order of processes.

First, as illustrated in the FIG. 4A, the buffer layer 12, the channel layer 13, the barrier layer 14, and the insulation film 16 are formed in this order on the substrate 11 configured by, for example, Si. The buffer layer 12, the channel layer 13, and the barrier layer 14 are formed by, for example, an epitaxial growth method. The channel layer 13 is formed, for example, by epitaxially growing a GaN layer on the buffer layer 12, and the barrier layer 14 is formed, for example, by epitaxially growing u-AlGaN (Al_{0.3}—Ga_{0.7}N mixed crystal) on the channel layer 13. The insulation film 16 is used as a selection mask upon forming the source-side contact region 15S and the drain-side contact region 15D in a later process. After forming the insulation film 16, for example, the element isolation is performed. The element isolation is performed, for example, by ion-implanting B (boron) or the like into a region between adjacent elements. By the ion implantation, the region between the elements is caused to be high in resistance, and the element isolation is achieved accordingly (the active region a illustrated in FIG. 2 is formed). The process of the element isolation may be performed in a later process (e.g., after the formation of the source-side contact region 15S and the drain-side contact region 15D, or after the formation of the gate electrode 23).

After the insulation film 16 is formed, etching is performed from the insulation film 16 to the channel layer 13 as illustrated in FIG. 4B. Thus, a pair of cutouts C is formed at a stack on the substrate 11. The pair of cutouts C reaches, for example, a portion of the channel layer 13, and a bottom surface of the cutout C is formed by the channel layer 13.

Next, as illustrated in FIG. 4C, for example, a selective regrowth method is used to form the source-side contact region 15S at one of the pair of cutouts C and the drain-side contact region 15D at the other of the pair of cutouts C. Thus, the semiconductor layer 10 is formed on the substrate 11. Here, the insulation film 16 (FIG. 4B) functions as a selective mask upon performing the selective regrowth method. After the source-side contact region 15S and the drain-side contact region 15D are formed, the insulation film 16 is removed by, for example, etching.

Next, as illustrated in FIG. 4D, the source-side contact region 15S is electrically coupled to form the source electrode 21S, and the drain-side contact region 15D is electrically coupled to form the drain electrode 21D. The source electrode 21S and the drain electrode 21D are formed by performing mask evaporation of titanium (Ti), aluminum (Al), nickel (Ni), and gold (Au) in this order on a surface of the semiconductor layer 10, for example. Thus, the source electrode 21S and the drain electrode 21D are patterned in selective regions of the surface of the semiconductor layer 10.

Next, for example, the interlayer insulation film 22 is formed on the entire surface of the semiconductor layer 10 so as to cover the source electrode 21S and the drain electrode 21D, as illustrated in FIG. 4E. The interlayer insulation film 22 is formed by forming a film of silicon oxide (SiO₂) using a CVD (Chemical Vapor Deposition) method, for example. For example, the interlayer insulation film 22 may be formed by forming a film of aluminum oxide (Al₂O₃) using an ALD (Atomic Layer Deposition) method, or may be formed by forming a film of silicon nitride (SiN) using a CVD method.

After the interlayer insulation film 22 is formed, the opening 22M is formed in a predetermined region of the interlayer insulation film 22 as illustrated in FIG. 4F. The opening 22M is formed, for example, by pattern-etching a portion of the interlayer insulation film 22 disposed between the source electrode 21S and the drain electrode 21D in the channel length direction. The opening 22M is formed, for example, to a depth that reaches the semiconductor layer 10.

After the opening 22M is formed, the gate electrode 23 is so formed in a predetermined region on the interlayer insulation film 22 as to bury the opening 22M. The gate electrode 23 is formed, for example, by performing mask evaporation of Ni (nickel) and Au (gold) sequentially on the interlayer insulation film 22. Through these processes, the semiconductor device 1 illustrated in FIGS. 1 and 2 is completed.

(Operation of Semiconductor Device 1)

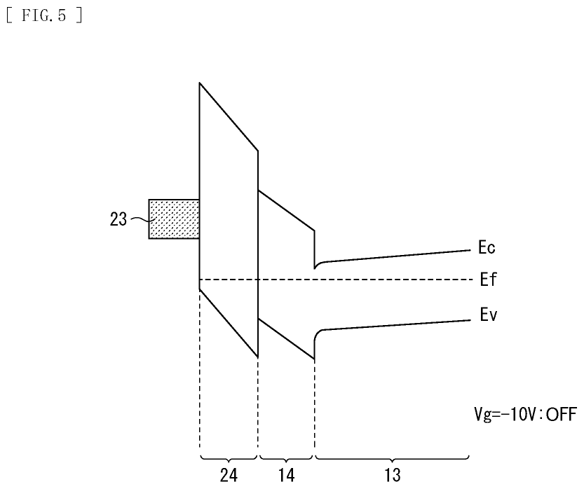

An operation of the semiconductor device 1 described above will be described with reference to an energy band configuration diagram of FIG. 5 and a cross-sectional diagram of the semiconductor device 1 of FIG. 6 in conjunction with FIG. 3 described previously. Here, an operation of the semiconductor device 1 will be described in which the semiconductor device 1 is of a depletion type transistor having a threshold voltage of about −5 V.

FIG. 5 illustrates a case at the time of an off operation (Vg=−10 V). Further, FIG. 5 illustrates a case where the channel layer 13 is configured by GaN and the barrier layer 14 is configured by an Al_{0.3}Ga_{0.7}N mixed crystal, as with a case of FIG. 3.

In the semiconductor device 1, when the negative gate voltage Vg (for example, about −10 V) is applied to the gate electrode 23, the number of carriers decreases in a region (a carrier deficiency region A) of the channel layer 13 immediately below the gate electrode 23, as illustrated by a cross-sectional diagram of FIG. 6. Thus, the number of electrons in the channel layer 13 decreases, and a drain current Id hardly flows. An energy band configuration at this time is as illustrated in FIG. 5, and a conduction band energy Ec in the channel layer 13 becomes completely higher than the Fermi level Ef.

In contrast, when the positive gate voltage Vg (e.g., about 1 V) is applied to the gate electrode 23, a state at the time of on operation is established. In this case, the carrier deficiency region A illustrated by the cross-sectional diagram of FIG. 6 disappears, increasing the number of electrons in the channel layer 13 and modulating the drain current Id. The energy band configuration at this time is as illustrated in FIG. 3, and the conduction band energy Ec in the channel layer 13 becomes lower than the Fermi level Ef.

(Workings and Effects of Semiconductor Device)

In the semiconductor device 1 of the present embodiment, the source electrode 21S extends more in the channel length direction than the source-side contact region 15S and the drain electrode 21D extends more in the channel length direction than the drain-side contact region 15D. This suppresses an influence of the sheet resistance of the source-side contact region 15S and the drain-side contact region 15D as compared with a case in which the source-side contact region 15S and the drain-side contact region 15D are respectively exposed from the source electrode 21S and the drain electrode 21D in the channel length direction. Hereinafter, workings and effects thereof will be described.

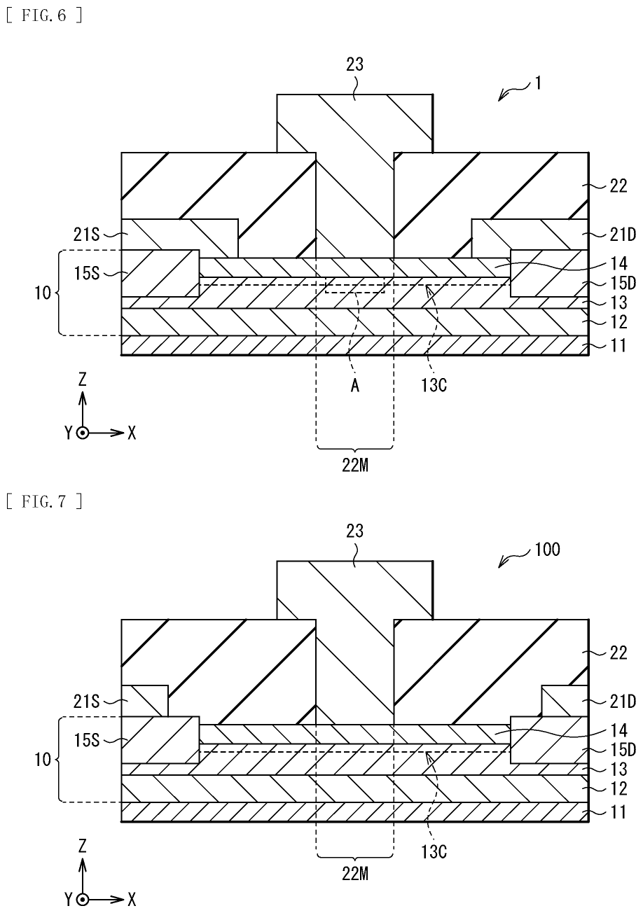

FIG. 7 schematically illustrates a cross-sectional configuration of a main part of a semiconductor device (a semiconductor device 100) according to a comparative example. FIG. 7 corresponds to FIG. 1 that represents the semiconductor device 1. The semiconductor device 100 has the semiconductor layer 10 on the substrate 11. The semiconductor device 100 is, for example, a GaN-based HFET as with the semiconductor device 1. The semiconductor layer 10 includes the buffer layer 12, the channel layer 13, and the barrier layer 14 in order from the substrate 11 side. The semiconductor layer 10 has the source-side contact region 15S and the drain-side contact region 15D at predetermined sizes from a surface in a thickness direction. In the semiconductor device 100, the source-side contact region 15S is provided to extend more on the gate electrode 23 side than the source electrode 21S, and the drain-side contact region 15D is provided to extend more on the gate electrode 23 side than the drain electrode 21D. That is, a portion of the source-side contact region 15S is exposed from the source electrode 21S, and a portion of the drain-side contact region 15D is exposed from the drain electrode 21D. In this respect, the semiconductor device 100 differs from the semiconductor device 1.

In such a semiconductor device 100, the on resistance (Ron) can increase due to the sheet resistance of the source-side contact region 15S of the portion exposed from the source electrode 21S and the sheet resistance of the drain-side contact region 15D of the portion exposed from the drain electrode 21D. In particular, the on resistance tends to become high if the drain-side contact region 15D to which a high voltage is applied is exposed from the drain electrode 21D.

Further, an interface trap is likely to occur in the vicinity of an interface between the barrier layer 14 and the interlayer insulation film 22, and a characteristic of the semiconductor device 100 can deteriorate due to the interface trap. In particular, an influence of the interface trap becomes large in the semiconductor device 100 that uses the GaN (gallium nitride)-based semiconductor layer 10. Accordingly, there is a possibility that a characteristic variation can occur in the semiconductor device 100 after application of a voltage to the gate electrode 23 and the drain electrode 21D. As a method for suppressing the deterioration of the characteristic of the semiconductor device 100 caused by the interface trap, a method using a field plate effect may be considered (for example, Japanese Unexamined Patent Application Publication No. 2016-136547). However, a capacitance between a gate and a drain is increased in the method that uses the field plate effect. The capacitance between the gate and the drain is formed at a portion where the gate electrode and the drain-side two dimensional electron gas layer are opposed to each other in a stacking direction and at a portion where the gate electrode and the drain electrode are close to each other in the channel length direction. There is a possibility that a frequency characteristic is decreased due to the increase in the capacitance between the gate and the drain. Further, a distance between the gate and the drain is increased by a field plate in the method that uses the field plate effect, which can lead to an easier increase in a device size.

In addition, a surface of the portions of the semiconductor layer 10 exposed from the source electrode 21S and the drain electrode 21D can deteriorate due to a treatment during a manufacturing process. For example, the semiconductor layer 10 can deteriorate and the sheet resistance of the two dimensional electron gas layer 13c can increase, due to a process prior to the formation of the interlayer insulation film 22, plasma irradiation upon the formation of the interlayer insulation film 22 and the like.

In contrast, in the semiconductor device 1, the source electrode 21S extends more in the channel length direction than the source-side contact region 15S, and the drain electrode 21D extends more in the channel length direction than the drain-side contact region 15D. That is, the source-side contact region 15S and the drain-side contact region 15D do not expose from the source electrode 21S and the drain electrode 21D, thereby suppressing the influence of the sheet resistance of the source-side contact region 15S and the drain-side contact region 15D of the portions exposed from the source electrode 21S and the drain electrode 21D. Thus, the on resistance is reduced in the semiconductor device 1.

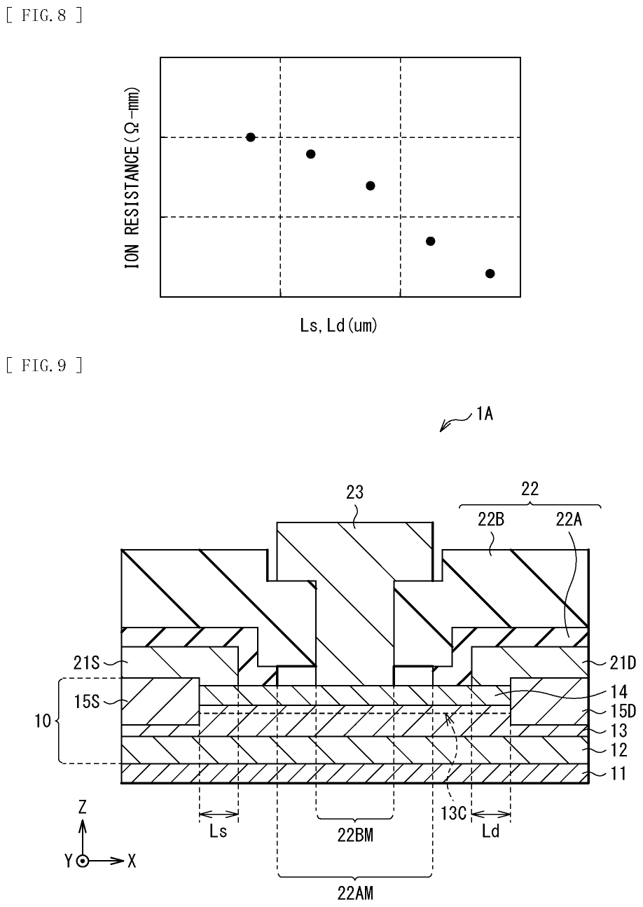

FIG. 8 illustrates a relationship between the on resistance of the semiconductor device 1 and distances Ls and Ld. It was confirmed that the on resistance of the semiconductor device 1 decreases as the distance Ls (FIGS. 1 and 2) of the source electrode 21S of the portion extending more on the gate electrode 23 side than the source-side contact region 15S increases, and as the distance Ld (FIGS. 1 and 2) of the drain electrode 21D of the portion extending more on the gate electrode 23 side than the drain-side contact region 15D increases.

Further, in the semiconductor device 1, the area of the interface between the barrier layer 14 and the interlayer insulation film 22 becomes smaller than that of the semiconductor device 100 by extending the source electrode 21S and the drain electrode 21D more in the channel length direction than the source-side contact region 15S and the drain-side contact region 15D. This suppresses the degradation of the characteristic of the semiconductor device 1 caused by the interface trap in the vicinity of the interface between the barrier layer 14 and the interlayer insulation film 22. In particular, in the semiconductor device 1 having the GaN (gallium nitride)-based semiconductor layer 10, the degradation of the characteristic caused by the interface trap is effectively suppressed. Hence, it is possible to suppress the characteristic variation of the semiconductor device 1 following the application of the voltage to the gate electrode 23 and the drain electrode 21D. Further, in the semiconductor device 1, the influence of the interface trap is suppressed without using the field plate effect. Hence, it is possible to suppress the decrease in frequency characteristic due to the increase in the capacitance between the gate and the drain and to suppress the increase in the device size.

Further, in the semiconductor device 1, surfaces of the semiconductor layer 10 of the portions exposed from the source electrode 21S and the drain electrode 21D become small as compared with the semiconductor device 100 by extending the source electrode 21S and the drain electrode 21D more in the channel length direction than the source-side contact region 15S and the drain-side contact region 15D. Thus, it is possible to suppress the deterioration of the semiconductor layer 10 caused by a treatment in a manufacturing process and to suppress the increase in the sheet resistance of the two dimensional electron gas layer 13c.

In addition, in the semiconductor device 1, portions in which the two dimensional electron gas layer 13c and each of the source electrode 21S and the drain electrode 21D face each other are formed in the stacking direction (the Z-axis direction in FIG. 1). Thus, it is possible to stabilize a potential distribution inside the channel layer 13 and to improve a high-frequency characteristic.

As described above, in the present embodiment, the source electrode 21S is provided so as to extend more on at least the gate electrode 23 side than the source-side contact region 15S, and the drain electrode 21D is provided so as to extend more on at least the gate electrode 23 side than the drain-side contact region 15D. Thus, it is possible to suppress the influence of the sheet resistance of the source-side contact region 15S and the drain-side contact region 15D and to reduce the on resistance. Accordingly, it is possible to improve a transistor characteristic.

It should be noted that, in the above embodiment, a case has been described where the semiconductor device 1 is of the depletion type, but it is possible to similarly consider a case where the semiconductor device 1 is of an enhancement type.

Hereinafter, modification examples of the above-described embodiment will be described. In the following description, the same components as those of the above-described embodiment are denoted by the same reference numerals, and the description thereof will be omitted as appropriate.

### Modification Example 1

FIG. 9 schematically illustrates a cross-sectional configuration of a main part of the semiconductor device (a semiconductor device 1A) according to modification example 1 of the above embodiment. FIG. 9 corresponds to FIG. 1 that represents the semiconductor device 1. The semiconductor device 1A has a planar configuration similar to that of the semiconductor device 1 (FIG. 2). In the semiconductor device 1A, the interlayer insulation film 22 has a stacked structure including a first interlayer insulation film 22A and a second interlayer insulation film 22B. Except for this point, the semiconductor device 1A has a similar configuration to the semiconductor device 1, and its workings and effects are similar to those of the semiconductor device 1 as well.

The interlayer insulation film 22 is configured by a laminated film in which the first interlayer insulation film 22A and the second interlayer insulation film 22B are stacked in order from the barrier layer 14 side. The first interlayer insulation film 22A has a first opening 22AM, and the second interlayer insulation film 22B has a second opening 22BM. The gate electrode 23 is embedded in the first opening 22AM and the second opening 22BM.

The first interlayer insulation film 22A is provided between the barrier layer 14 and the second interlayer insulation film 22B and between the source electrode 21S or the drain electrode 21D and the second interlayer insulation film 22B. The first interlayer insulation film 22A is configured by, for example, Al₂O₃ (aluminum oxide). Such a first interlayer insulation film 22A functions as an insulation film for the barrier layer 14 and also has a function of protecting a surface of the barrier layer 14 from contamination by impurities. Examples of the impurity include ions. In addition, by forming a good interface between the first interlayer insulation film 22A and the barrier layer 14, a deterioration of a device characteristic is suppressed. The first interlayer insulation film 22A is preferably configured by a wet etchable material, and a selection ratio of the wet etching between a constituent material of the second interlayer insulation film 22B and a constituent material of the first interlayer insulation film 22A is, for example, 1:1 or more, and preferably 1:5 or more. The first opening 22AM provided at the first interlayer insulation film 22A penetrates through the first interlayer insulation film 22A.

The second interlayer insulation film 22B faces the barrier layer 14 with the first interlayer insulation film 22A therebetween. The second interlayer insulation film 22B has the second opening 22BM having a width smaller than a width in the channel length direction (a size in the X-axis direction in FIG. 9) of the first opening 22AM of the first interlayer insulation film 22A. The second opening 22BM of the second interlayer insulation film 22B is communicated with the first opening 22AM of the first interlayer insulation film 22A, and the gate electrode 23 is inserted through both the first opening 22AM and the second opening 22BM. For example, the second opening 22BM is disposed in the middle of the first opening 22AM in a plan view (an X-Y plane in FIG. 9). The second opening 22BM of the second interlayer insulation film 22B defines a size of the gate electrode 23 of a portion buried in the interlayer insulation film 22. By providing the first opening 22AM and the second opening 22BM, a void is formed between the gate electrode 23 and a side wall of the first opening 22AM. A dielectric constant of the void is lower than a dielectric constant of the interlayer insulation film 22. Thus, a gate-to-drain capacitance (Cgd) and a gate-to-source capacitance (Cgs) are lower in the semiconductor device 1A than in the semiconductor device 1 without the void, thereby making it possible to improve a gain.

The second interlayer insulation film 22B is configured by, for example, SiO₂ (silicon oxide). Such a second interlayer insulation film 22B, together with the first interlayer insulation film 22A, functions as an insulation film for the barrier layer 14 and has a function of protecting a surface of the barrier layer 14 from contamination by impurities. The second interlayer insulation film 22B is preferably configured by a dry-etchable material, and a selection ratio of the dry etching of a constituent material of the first interlayer insulation film 22A and a constituent material of the second interlayer insulation film 22B is, for example, 1:1 or more, and preferably 1:5 or more.

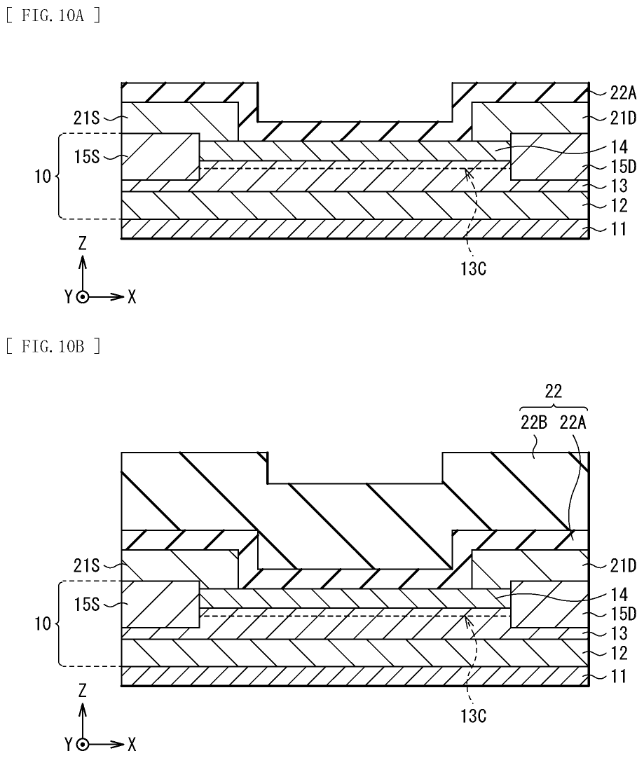

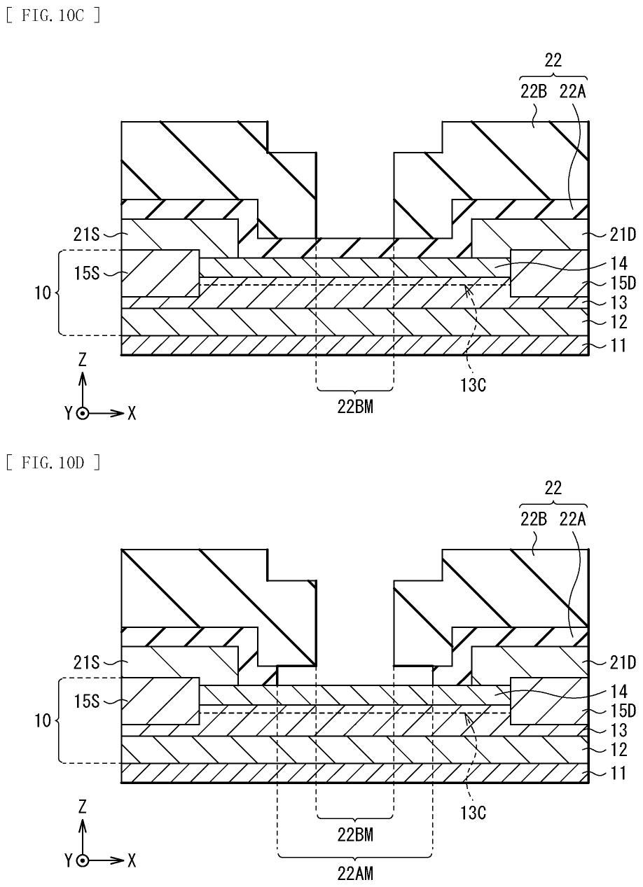

For example, it is possible to form the semiconductor device 1A as follows (FIGS. 10A to 10D).

First, the semiconductor layer 10, the source electrode 21S, and the drain electrode 21D are formed on the substrate 11 as with the embodiment described above (FIG. 4D).

Next, as illustrated in FIG. 10A, the first interlayer insulation film 22A is so formed over the entire surface of the semiconductor layer 10 as to cover the source electrode 21S and the drain electrode 21D. The first interlayer insulation film 22A is formed, for example, by forming a film of aluminum oxide (Al₂O₃) using an ALD method.

Next, as illustrated in FIG. 10B, the second interlayer insulation film 22B is formed on the first interlayer insulation film 22A. The second interlayer insulation film 22B is formed, for example, by forming a film of silicon oxide (SiO₂) by a CVD method.

Subsequently, as illustrated in FIG. 10C, the second opening 22BM is formed on the second interlayer insulation film 22B. The second opening 22BM penetrates the second interlayer insulation film 22B and reaches the first interlayer insulation film 22A. The second opening 22BM is preferably formed by dry-etching, for example. This makes it possible to suppress an increase in a width of the second opening 22BM. Further, by setting an etching selection ratio of a constituent material of the first interlayer insulation film 22A and a constituent material of the second interlayer insulation film 22B to 1:5 or more, it is possible to suppress a deterioration of the semiconductor layer 10 due to a film loss of the first interlayer insulation film 22A upon the formation of the second opening 22BM.

After the second opening 22BM is formed, the first opening 22AM is formed on the first interlayer insulation film 22A as illustrated in FIG. 10D. The first opening 22AM is preferably formed by wet etching, for example. Thus, it is possible to suppress a deterioration of the semiconductor layer 10 as compared with a case where the first opening 22AM is formed by dry-etching. In this modification example, the interlayer insulation film 22 is configured by the stacked structure including the first interlayer insulation film 22A and the second interlayer insulation film 22B, making it possible to form the first opening 22AM of the first interlayer insulation film 22A which is closer to the semiconductor layer 10 by wet etching. This suppresses a deterioration of the semiconductor layer 10 caused by a treatment in a manufacturing process.

In addition, by setting the etching selection ratio of the constituent material of the first interlayer insulation film 22A and the constituent material of the second interlayer insulation film 22B to 5:1 or more, it is possible to suppress an increase in a width of the second opening 22BM upon the formation of the first opening 22AM.

After the first opening 22AM is formed, the gate electrode 23 is formed so as to bury the second opening 22BM and the first opening 22AM from the above of the interlayer insulation film 22 (more specifically, the second interlayer insulation film 22B). It is possible to form the gate electrode 23 in a similar manner to that described in the above embodiment. For example, it is possible to form the semiconductor device 1A as described above.

In the semiconductor device 1A of the present modification example as well, the source electrode 21S is provided so as to extend more on at least the gate electrode 23 side than the source-side contact region 15S, and the drain electrode 21D is provided so as to extend more on at least the gate electrode 23 side than the drain-side contact region 15D, as with the semiconductor device 1 described above. Thus, it is possible to suppress the influence of the sheet resistance of the source-side contact region 15S and the drain-side contact region 15D and to reduce the on resistance. Accordingly, it is possible to improve a transistor characteristic.

In addition, the interlayer insulation film 22 has the stacked structure including the first interlayer insulation film 22A and the second interlayer insulation film 22B in order from the barrier layer 14 side. Thus, a surface of the semiconductor layer 10 is covered with the first interlayer insulation film 22A upon the formation of the second opening 22BM of the second interlayer insulation film 22B. For this reason, the surface of the semiconductor layer 10 is protected by the first interlayer insulation film 22A from the dry etching upon the formation of the second opening 22BM. Hence, a degradation of the semiconductor layer 10 immediately below the gate electrode 23 due to a treatment in a manufacturing process is suppressed. Accordingly, in the semiconductor device 1A, it is possible to improve a gate characteristic such as a reduction of a resistance or an improvement of a withstand voltage.

In addition, the gate-to-drain capacitance (Cgd) and the gate-to-source capacitance (Cgs) become low owing to the void provided between the gate electrode 23 and the side wall of the first opening 22AM. Accordingly, it is possible to improve the gain.

### Modification Example 2

FIG. 11 schematically illustrates a cross-sectional configuration of a main part of the semiconductor device (a semiconductor device 1B) according to modification example 2 of the above embodiment. FIG. 11 corresponds to FIG. 1 that represents the semiconductor device 1. The semiconductor device 1B has a planar configuration similar to that of the semiconductor device 1 (FIG. 2). The semiconductor device 1B has a gate insulation film (the gate insulation film 24) between the semiconductor layer 10 and the gate electrode 23. Except for this point, the semiconductor device 1B has a similar configuration to the semiconductor device 1 or 1A, and its workings and effects are similar to those of the semiconductor device 1 or 1A as well.

The gate insulation film 24 is provided so as to cover the side walls of the first opening 22AM and the second opening 22BM and cover a bottom surface of the second opening 22BM, for example, from the above of the interlayer insulation film 22 (specifically, the second interlayer insulation film 22B). The gate insulation film 24 provided on the bottom surface of the second opening 22BM is disposed between the semiconductor layer 10 (specifically, the barrier layer 14) and the gate electrode 23. That is, the semiconductor device 1 has a MIS (Metal Insulator Semiconductor) structure. Thus, a generation of a leakage current, a decrease in withstand voltage characteristic, and the like due to a contact between the gate electrode 23 and the semiconductor layer 10 are suppressed. That is, it is possible for the semiconductor device 1B to improve a gate characteristic as compared with the semiconductor device 1 or 1A.

The gate insulation film 24 is configured by, for example, Al₂O₃ or HfO₂ (hafnium oxide) having a thickness of about 10 nm. The gate insulation film 24 may be configured by a single layer or may have a stacked structure. Such a gate insulation film 24 functions as an insulation film for the barrier layer 14 and the interlayer insulation film 22 and also has a function of protecting a surface of the barrier layer 14 from contamination by impurities. Examples of the impurity include ions. In addition, by forming a good interface between the gate insulation film 24 and the barrier layer 14, a deterioration of a device characteristic is suppressed.

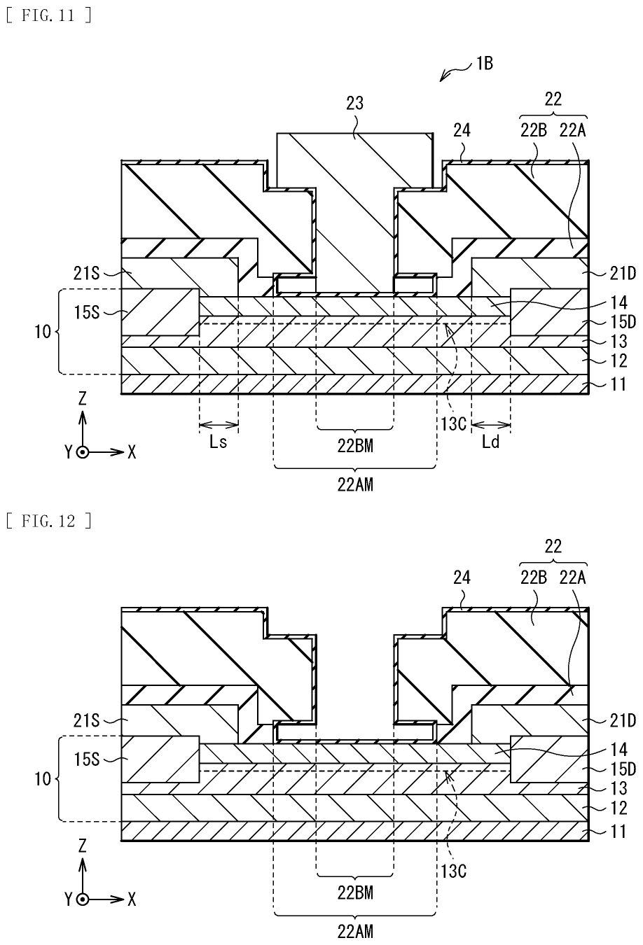

For example, it is possible to form the semiconductor device 1B as follows (FIG. 12).

First, the semiconductor layer 10, the source electrode 21S, the drain electrode 21D, the first interlayer insulation film 22A, and the second interlayer insulation film 22B are formed in this on the substrate 11 (FIG. 10B), following which the second opening 22BM and the first opening 22AM are formed (FIG. 10C and FIG. 10D), as with the modification example 1 described above.

Next, as illustrated in FIG. 12, the gate insulation film 24 is formed from the above of the second interlayer insulation film 22B so as to cover the side walls of the second opening 22BM and the first opening 22AM and the bottom surface of the first opening 22AM. The gate insulation film 24 is formed, for example, by forming a film of Al₂O₃ (aluminum oxide) by an ALD method. By using the ALD method, it is possible to perform a homogeneous film formation. Thus, exposed surfaces of the barrier layer 14, the first interlayer insulation film 22A, and the second interlayer insulation film 22B are coated with a homogeneous film.

After the gate insulation film 24 is formed, the gate electrode 23 is formed so as to bury the second opening 22BM and the first opening 22AM from the above of the interlayer insulation film 22 (more specifically, the second interlayer insulation film 22B). It is possible to form the gate electrode 23 in a similar manner to that described in the above embodiment. For example, it is possible to form the semiconductor device 1B as described above.

In the semiconductor device 1B of the present modification example as well, the source electrode 21S is provided so as to extend more on at least the gate electrode 23 side than the source-side contact region 15S, and the drain electrode 21D is provided so as to extend more on at least the gate electrode 23 side than the drain-side contact region 15D, as with the semiconductor device 1 described above. Thus, it is possible to suppress the influence of the sheet resistance of the source-side contact region 15S and the drain-side contact region 15D and to reduce the on resistance. Accordingly, it is possible to improve a transistor characteristic.

In addition, the gate insulation film 24 is provided between the semiconductor layer 10 (specifically, the barrier layer 14) and the gate electrode 23. Thus, the generation of the leakage current, the decrease in withstand voltage characteristic, and the like due to the contact between the gate electrode 23 and the semiconductor layer 10 are suppressed. That is, it is possible for the semiconductor device 1B to improve a gate characteristic as compared with the semiconductor device 1 or 1A.

### Application Example

It is possible to apply the semiconductor device 1, 1A, and 1B described in the embodiment and the modification examples 1 and 2 described above to various electronic apparatuses. For example, the semiconductor device 1, 1A, or 1B is used for a wireless communicator in a mobile communication system or the like, and in particular, is used as an RF switch, a power amplifier, or the like thereof. It is particularly effective for a wireless communicator whose communication frequency is equal to or higher than an UHF (ultra high frequency) band.

In other words, by using the semiconductor device 1, 1A, or 1B for the RF switch and the power amplifier of the wireless communicator, it is possible to achieve a higher speed, a higher efficiency, and a lower power consumption of the wireless communicator. In particular, a higher speed, a higher efficiency, and a lower power consumption of a device makes it possible to extend the use time of a portable communication terminal. Hence, it is possible to improve portability.

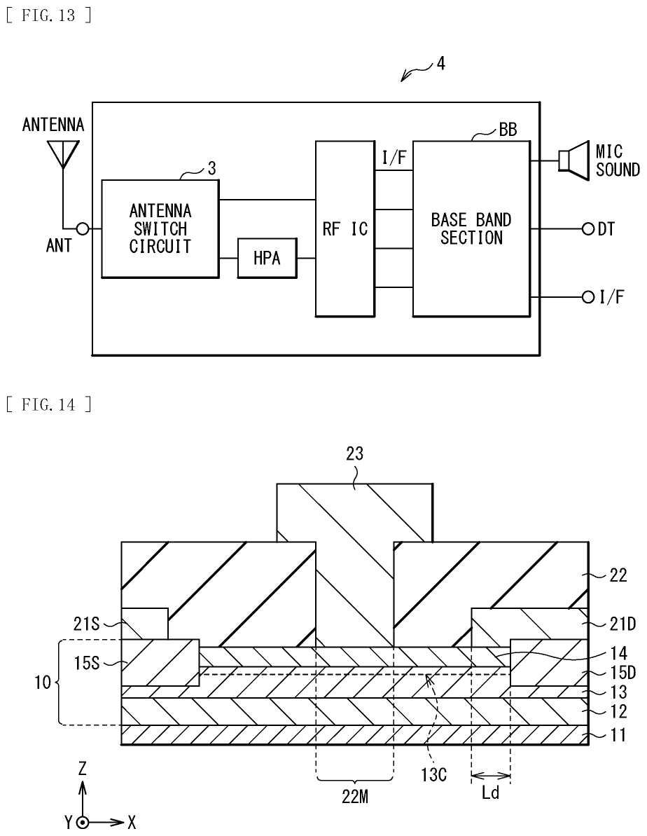

FIG. 13 illustrates an example of a configuration of a wireless communicator (a wireless communicator 4). The wireless communicator 4 is, for example, a mobile telephone system having a variety of functions such as sound, data communication, and LAN connection. The wireless communicator 4 includes, for example, an antenna ANT, an antenna switch circuit 3, a high-power amplifier HPA, a high-frequency integrated circuit RFIC (Radio Frequency Integrated Circuit), a base band section BB, a sound output section MIC, a data output section DT, and an interface I/F (e.g., wireless LAN (W-LAN; Wireless Local Area Network), Bluetooth (registered trademark), etc.). The high-frequency integrated circuit RFIC and the base band section BB are coupled by the interface I/F. For example, the antenna switch circuit 3, the high-power amplifier HPA, or the high-frequency integrated circuit RFIC includes any of the semiconductor devices 1, 1A, and 1B described above. Here, the antenna switch circuit 3, the high-power amplifier HPA, or the high-frequency integrated circuit RFIC corresponds to one concrete example of a semiconductor module according to the present disclosure.

In the wireless communicator 4, at the time of transmission, i.e., when a transmission signal is to be outputted from a transmission system of the wireless communicator 4 to the antenna ANT, a transmission signal to be outputted from the base band section BB is outputted to the antenna ANT via the high-frequency integrated circuit RFIC, the high-power amplifier HPA, and the antenna switch circuit 3.

At the time of reception, i.e., when a signal received by the antenna ANT is to be inputted to a reception system of the wireless communicator, the received signal is inputted to the base band section BB via the antenna switch circuit 3 and the high-frequency integrated circuit RFIC. A signal processed by the base band section BB is outputted from an output unit such as the sound output section MIC, the data output section DT, or the interface I/F.

Although the present technology has been described with reference to the embodiment and the modification examples, the present technology is not limited to the embodiment and the like, and various modifications can be made. For example, the constituent elements, the arrangement, the number, and the like of the semiconductor devices 1, 1A, and 1B exemplified in the above embodiment and the like are merely illustrative. It is not necessary to include all the constituent elements, and may further include other constituent elements.

In addition, a material and a thickness of each layer, or a film forming method, a film forming condition, and the like described in the above embodiment and the like are non-limiting, and any other material and thicknesses may be employed, or any other film forming method and any other film forming condition may be employed. For example, in the above embodiment and the like, a case has been described in which the semiconductor layer 10 is configured by the GaN-based compound semiconductor material. However, the semiconductor layer 10 may be configured by any other compound semiconductor material such as GaAs (gallium arsenide), or may be configured by a semiconductor material such as Si (silicon).

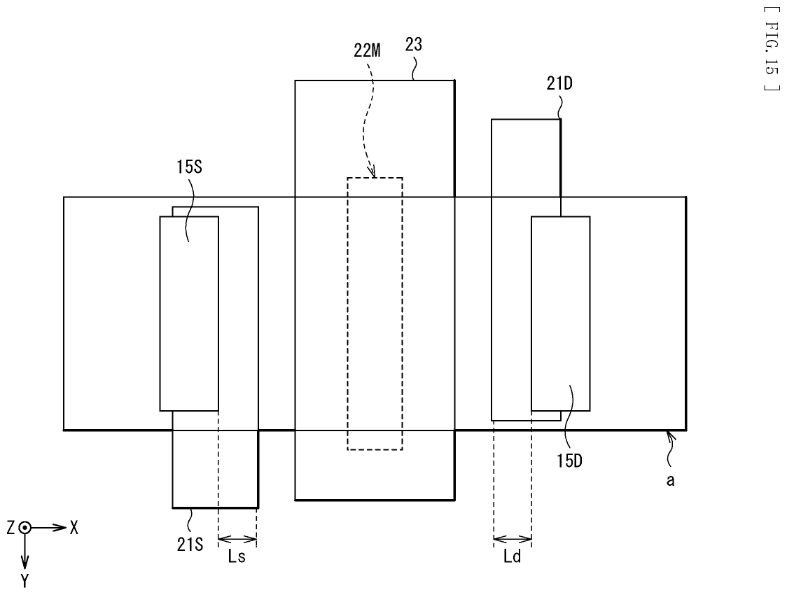

Further, in the semiconductor device 1, 1A, or 1B, at least one of the source electrode 21S or the drain electrode 21D may extend more in the channel length direction than the source-side contact region 15S and the drain-side contact region 15D. For example, as illustrated in FIG. 14, the drain electrode 21D may extend more on the gate electrode 23 side than the drain-side contact region 15D, and a portion of the source-side contact region 15S on the gate electrode 23 side may be exposed from the source electrode 21S. It is preferable that at least the drain electrode 21D extend more on the gate electrode 23 side than the drain-side contact region 15D.

Further, in the semiconductor device 1, 1A, or 1B, the source electrode 21S and the drain electrode 21D may extend more in the channel length direction than the source-side contact region 15S and the drain-side contact region 15D on at least the gate electrode 23 side. For example, as illustrated in FIG. 15, the source electrode 21S and the drain electrode 21D may extend more on the gate electrode 23 side than the source-side contact region 15S and the drain-side contact region 15D, and portions of the respective source-side contact region 15S and drain-side contact region 15D may be exposed from the source electrode 21S and the drain electrode 21D on the opposite side of the gate electrode 23.

Note that the effect described in this specification is merely exemplary and is not limited thereto, and other effects may be obtained.

The present technology may be configured as follows. According to the semiconductor device having the following configuration, and the semiconductor module and the electronic apparatus that include the semiconductor device, an electrode is provided so as to extend more on at least the gate electrode side than the contact region. Thus, it is possible to suppress an influence of the sheet resistance of the contact region and to reduce the on resistance. Hence, it is possible to improve a transistor characteristic.

(1)

A semiconductor device including:

a semiconductor layer including a channel layer;

a contact region provided at a predetermined size in a thickness direction of the semiconductor layer, and having an impurity concentration that is higher than an impurity concentration of the surrounding semiconductor layer;

a gate electrode facing the channel layer, and provided on the semiconductor layer and spaced from the contact region; and

an electrode that is in contact with the semiconductor layer and electrically coupled to the channel layer via the contact region, and extending more on at least the gate electrode side than the contact region.

(2)

The semiconductor device according to (1), in which the semiconductor layer includes a compound semiconductor material.

(3)

The semiconductor device according to (1) or (2), in which

the contact region includes a source-side contact region provided on one side of the gate electrode, and a drain-side contact region provided on the other side of the gate electrode, and

the electrode includes a source electrode electrically coupled to the channel layer via the source-side contact region, and a drain electrode electrically coupled to the channel layer via the drain-side contact region.

(4)

The semiconductor device according to any one of (1) to (3), in which the electrode also extends more on an opposite side of the gate electrode than the contact region.

(5)

The semiconductor device according to any one of (1) to (4), in which the contact region is provided from a surface of the semiconductor layer over at least a portion in the thickness direction of the channel layer.

(6)

The semiconductor device according to any one of (1) to (5), in which the electrode is in contact with the contact region.

(7)

The semiconductor device according to any one of (1) to (6), further including an interlayer insulation film that covers the electrode and the semiconductor layer and has an opening in a selective region, in which

the gate electrode is embedded in the opening of the interlayer insulation film.

(8)

The semiconductor device according to (7), in which

the interlayer insulation film has a stacked structure including a first interlayer insulation film and a second interlayer insulation film in order from the semiconductor layer side, and

the opening includes a first opening provided on the first interlayer insulation film, and a second opening provided on the second interlayer insulation film.

(9)

The semiconductor device according to (8), in which

the first opening is communicated with the second opening, and

a width of the first opening is greater than a width of the second opening.

(10)

The semiconductor device according to any one of (1) to (9), further including a gate insulation film provided between the gate electrode and the semiconductor layer.

(11)

The semiconductor device according to any one of (1) to (10), in which

the semiconductor layer further includes a barrier layer provided between the channel layer and the gate electrode, and

the barrier layer includes a semiconductor material having a band gap greater than a band gap of the channel layer.

(12)

A semiconductor module with a semiconductor device, the semiconductor device including:

a semiconductor layer including a channel layer;

a contact region provided at a predetermined size in a thickness direction of the semiconductor layer, and having an impurity concentration that is higher than an impurity concentration of the surrounding semiconductor layer;

a gate electrode facing the channel layer, and provided on the semiconductor layer and spaced from the contact region; and

an electrode that is in contact with the semiconductor layer and electrically coupled to the channel layer via the contact region, and extending more on at least the gate electrode side than the contact region.

(13)

An electronic apparatus with a semiconductor device, the semiconductor device including:

a semiconductor layer including a channel layer;

a contact region provided at a predetermined size in a thickness direction of the semiconductor layer, and having an impurity concentration that is higher than an impurity concentration of the surrounding semiconductor layer;

a gate electrode facing the channel layer, and provided on the semiconductor layer and spaced from the contact region; and

an electrode that is in contact with the semiconductor layer and electrically coupled to the channel layer via the contact region, and extending more on at least the gate electrode side than the contact region.

The present application claims the benefit of Japanese Priority Patent Application JP2019-147801 filed with the Japan Patent Office on Oct. 9, 2019, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a semiconductor layer including a channel layer;
a contact region provided at a predetermined size in a thickness direction of the semiconductor layer, and having an impurity concentration that is higher than an impurity concentration of the surrounding semiconductor layer;
a gate electrode facing the channel layer, and provided on the semiconductor layer and spaced from the contact region; and
an electrode that is in contact with the semiconductor layer and electrically coupled to the channel layer via the contact region, and extending more on at least the gate electrode side than the contact region.

2. The semiconductor device according to claim 1, wherein the semiconductor layer includes a compound semiconductor material.

3. The semiconductor device according to claim 1, wherein
the contact region includes a source-side contact region provided on one side of the gate electrode, and a drain-side contact region provided on the other side of the gate electrode, and
the electrode includes a source electrode electrically coupled to the channel layer via the source-side contact region, and a drain electrode electrically coupled to the channel layer via the drain-side contact region.

4. The semiconductor device according to claim 1, wherein the electrode also extends more on an opposite side of the gate electrode than the contact region.

5. The semiconductor device according to claim 1, wherein the contact region is provided from a surface of the semiconductor layer over at least a portion in the thickness direction of the channel layer.

6. The semiconductor device according to claim 1, wherein the electrode is in contact with the contact region.

7. The semiconductor device according to claim 1, further comprising an interlayer insulation film that covers the electrode and the semiconductor layer and has an opening in a selective region, wherein
the gate electrode is embedded in the opening of the interlayer insulation film.

8. The semiconductor device according to claim 7, wherein
the interlayer insulation film has a stacked structure including a first interlayer insulation film and a second interlayer insulation film in order from the semiconductor layer side, and
the opening includes a first opening provided on the first interlayer insulation film, and a second opening provided on the second interlayer insulation film.

9. The semiconductor device according to claim 8, wherein
the first opening is communicated with the second opening, and
a width of the first opening is greater than a width of the second opening.

10. The semiconductor device according to claim 1, further comprising a gate insulation film provided between the gate electrode and the semiconductor layer.

11. The semiconductor device according to claim 1, wherein
the semiconductor layer further includes a barrier layer provided between the channel layer and the gate electrode, and
the barrier layer includes a semiconductor material having a band gap greater than a band gap of the channel layer.

12. A semiconductor module with a semiconductor device, the semiconductor device comprising:
a semiconductor layer including a channel layer;
a contact region provided at a predetermined size in a thickness direction of the semiconductor layer, and having an impurity concentration that is higher than an impurity concentration of the surrounding semiconductor layer;
a gate electrode facing the channel layer, and provided on the semiconductor layer and spaced from the contact region; and
an electrode that is in contact with the semiconductor layer and electrically coupled to the channel layer via the contact region, and extending more on at least the gate electrode side than the contact region.

13. An electronic apparatus with a semiconductor device, the semiconductor device comprising:
a semiconductor layer including a channel layer;
a contact region provided at a predetermined size in a thickness direction of the semiconductor layer, and having an impurity concentration that is higher than an impurity concentration of the surrounding semiconductor layer;
a gate electrode facing the channel layer, and provided on the semiconductor layer and spaced from the contact region; and
an electrode that is in contact with the semiconductor layer and electrically coupled to the channel layer via the contact region, and extending more on at least the gate electrode side than the contact region.
